(19) United States
(12) Patent Application Publication
(10) Pub. No.: US 2025/0185495 A1
(43) Pub. Date: Jun. 5, 2025

(54) DISPLAY DEVICE AND METHOD OF MANUFACTURING THE DISPLAY DEVICE

(71) Applicant: Samsung Display Co., LTD., Yongin-si (KR)

(72) Inventors: Rangkyun MOK, Yongin-si (KR); Taeho LEE, Yongin-si (KR); Youngsang HA, Yongin-si (KR)

(21) Appl. No.: 18/961,289

(22) Filed: Nov. 26, 2024

(30) Foreign Application Priority Data
Dec. 5, 2023 (KR) 10-2023-0174890

(51) Int. Cl. H10K 59/80; B60K 35/22; G02F 1/167

(52) U.S. Cl. CPC H10K 59/8792; B60K 35/22; G02F 1/167; H10K 59/873

(57) ABSTRACT

Provided is a display device including a substrate including a display area and a peripheral area that is positioned outside the display area, a display layer in the display area, the display layer including an emission element, an encapsulation layer that covers the display layer, an electrode line on the encapsulation layer, the electrode line extending in a first direction, a first light-shielding line on the electrode line, where the first light-shielding line extends in the first direction, overlaps the electrode line, and includes a light-shielding material, a second light-shielding line on the first light-shielding line, where the second light-shielding line extends in a second direction that crosses the first direction and includes an electrophoretic solution, and an electrode layer on the second light-shielding line.

This application claims priority to Korean Patent Application No. 10-2023-0174890, filed on Dec. 5, 2023, and all the benefits accruing therefrom under 35 U.S.C. § 119, the content of which in its entirety is herein incorporated by reference.

### BACKGROUND

### 1. Field

One or more embodiments relate to a display device and a method of manufacturing the display device.

### 2. Description of the Related Art

The use of display devices has diversified. As display devices have become thinner and lighter, the range of use of display devices has widened, and with the use of display devices in various fields, the demand for display devices capable of providing high-quality images has increased. In some cases, display devices have been mounted inside vehicles to provide images to users seating in the driver's seat or the passenger seat.

### SUMMARY

Light emitted from a display device arranged inside a vehicle may be reflected from a vehicle window and may reach a user. In this case, the driver's field of view may be obstructed while driving, which may lead to safety problems while driving.

One or more embodiments include a display device with improved display quality, in which the emitted light may travel in a specific direction such that the user's field of view is not obstructed, and a vehicle including the display device. However, this objective is an example, and the scope of one or more embodiments is not limited thereby.

Additional aspects will be set forth in part in the description which follows and, in part, will be apparent from the description, or may be learned by practice of the presented embodiments of the disclosure.

According to one or more embodiments, a display device includes a substrate including a display area and a peripheral area that is disposed outside the display area, a display layer in the display area, the display layer including an emission element, an encapsulation layer that covers the display layer, an electrode line on the encapsulation layer, the electrode line extending in a first direction, a first light-shielding line on the electrode line, wherein the first light-shielding line extends in the first direction, overlaps the electrode line, and includes a light-shielding material, a second light-shielding line on the first light-shielding line, wherein the second light-shielding line extends in a second direction that crosses the first direction and includes an electrophoretic solution, and an electrode layer on the second light-shielding line.

The electrophoretic solution may include a transparent fluid and light-shielding particles dispersed in the transparent fluid.

A width of the second light-shielding line may be greater than a width of the first light-shielding line.

The display device may further include an organic layer on the first light-shielding line, the organic layer including a groove that extends in the second direction, and the second light-shielding line is arranged in the groove of the organic layer.

The groove may pass through the organic layer.

A depth of the groove may be less than a thickness of the organic layer.

The second light-shielding line may contact the first light-shielding line.

The second light-shielding line may be spaced apart from the first light-shielding line.

The display device may further include a capping layer between the second light-shielding line and the electrode layer.

The display device may further include a passivation layer between the first light-shielding line and the electrode line.

According to one or more embodiments, a method of manufacturing a display device includes forming an electrode line on an encapsulation layer that covers an emission element, the electrode line extending in a first direction, forming a first light-shielding line on the electrode line, wherein the first light-shielding line extends in the first direction, overlaps the electrode line, and includes a light-shielding material, forming an organic layer on the first light-shielding line, forming a groove in the organic layer, the groove extending in a second direction that crosses the first direction, forming a second light-shielding line by injecting an electrophoretic solution into the groove of the organic layer, and forming an electrode layer on the second light-shielding line.

The electrophoretic solution may include a transparent fluid and light-shielding particles dispersed in the transparent fluid.

A width of the second light-shielding line may be greater than a width of the first light-shielding line.

The forming of the groove may include forming the by etching the organic layer.

The forming of the groove may include forming the groove through an imprinting process.

The method may further include forming a preliminary electrode line and a preliminary first light-shielding line that are sequentially stacked, wherein forming the electrode line and the first light-shielding line may include etching the preliminary electrode line and the preliminary first light-shielding line, respectively.

The method may further include forming a passivation layer between the electrode line and the first light-shielding line.

The method may further include forming a preliminary electrode line, a preliminary passivation layer, and a preliminary first light-shielding line that are sequentially stacked, wherein forming the electrode line, the passivation layer, and the first light-shielding line may include etching the preliminary electrode line, the preliminary passivation layer, and the preliminary first light-shielding line, respectively.

The method may further include forming a capping layer between the second light-shielding line and the electrode layer.

The forming of the electrode line may include forming the electrode line through a sputtering process, and the forming of the first light-shielding line may be after the forming of the electrode line.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram schematically illustrating the exterior of a vehicle according to an embodiment;

FIGS. 2A and 2B are diagrams schematically illustrating the interior of a vehicle according to an embodiment;

FIG. 3 is a perspective view schematically illustrating a display device according to an embodiment;

FIG. 4 is a plan view schematically illustrating a display device according to an embodiment;

FIG. 5 is an equivalent circuit diagram schematically illustrating a sub-pixel according to an embodiment;

FIG. 6 is an enlarged view of some elements of a display device in enlarged region A in FIG. 4, according to an embodiment;

FIG. 7 is an enlarged view of some elements of a display device in enlarged region A in FIG. 4 in a case where no voltage is applied to an electrode line and an electrode layer, according to an embodiment;

FIG. 8 is a cross-sectional view schematically illustrating the display device in FIG. 7, taken along line I-I in FIG. 7, according to an embodiment;

FIG. 9 is an enlarged view of region B in FIG. 8 in a case where no voltage is applied to an electrode line and an electrode layer, according to an embodiment;

FIG. 10 is a cross-sectional view schematically illustrating the display device in FIG. 7, taken along line II-Il in FIG. 7, according to an embodiment;

FIG. 11 is an enlarged view of some elements of a display device in enlarged region A in FIG. 4 in a case where a voltage is applied to an electrode line and an electrode layer, according to an embodiment;

FIG. 12 is an enlarged view of region B in FIG. 8 in a case where a voltage is applied to an electrode line and an electrode layer, according to an embodiment;

FIG. 13 is a cross-sectional view schematically illustrating the display device in FIG. 7, taken along line I-I in FIG. 7, according to another embodiment;

FIGS. 14A to 14G are cross-sectional views schematically illustrating a method of manufacturing a display device, according to an embodiment; and

FIGS. 15A to 15D are cross-sectional views schematically illustrating a method of manufacturing a display device, according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b, or c” may indicate only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are illustrated. This disclosure may, however, be embodied in many different forms and should not be construed as limited to the embodiments set forth herein.

Hereinafter, embodiments will be described with reference to the accompanying drawings, wherein like reference numerals refer to like elements throughout and a repeated description thereof is omitted.

In an embodiment below, terms such as, for example, “first” and “second” are used herein merely to describe a variety of elements, but the elements are not limited by the terms. Such terms are used for the purpose of distinguishing one element from another element.

In an embodiment below, an expression used in the singular encompasses the expression of the plural, unless the expression has a clearly different meaning in the context.

In an embodiment below, it will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, the layer, region, or element can be directly or indirectly formed on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the disclosure is not limited thereto.

When an embodiment may be implemented differently, a certain process order may be performed differently from the described order. For example, two consecutively described processes may be performed substantially at the same time or performed in an order opposite to the described order. The term “substantially,” as used herein, means approximately or actually (e.g., within a threshold). The term “substantially perpendicular,” as used herein, means approximately or actually perpendicular. The term “substantially equal,” as used herein, means approximately or actually equal. The term “substantially the same,” as used herein, means approximately or actually the same.

Herein, “A and/or B” means A or B, or A and B. “At least one of A and B” means A or B, or A and B.

It will be understood that when a layer, region, or element is referred to as being “connected” to another layer, region, or element, the layer, region, or element may be “directly connected” to the other layer, region, or element or may be “indirectly connected” to the other layer, region, or element with other layer, region, or element therebetween. For example, it will be understood that when a layer, region, or element is referred to as being “electrically connected” to another layer, region, or element, the layer, region, or element may be “directly electrically connected” to the other layer, region, or element or may be “indirectly electrically connected” to other layer, region, or element with other layer, region, or element therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

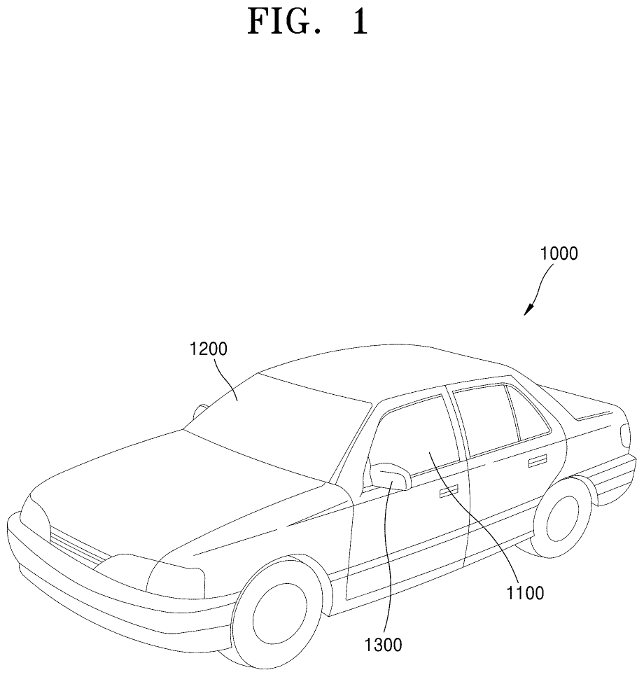

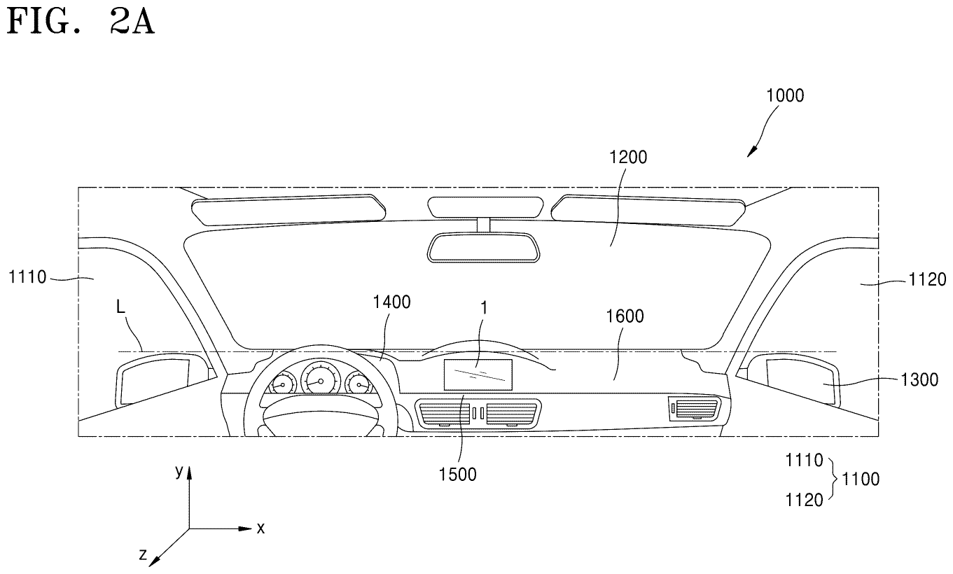

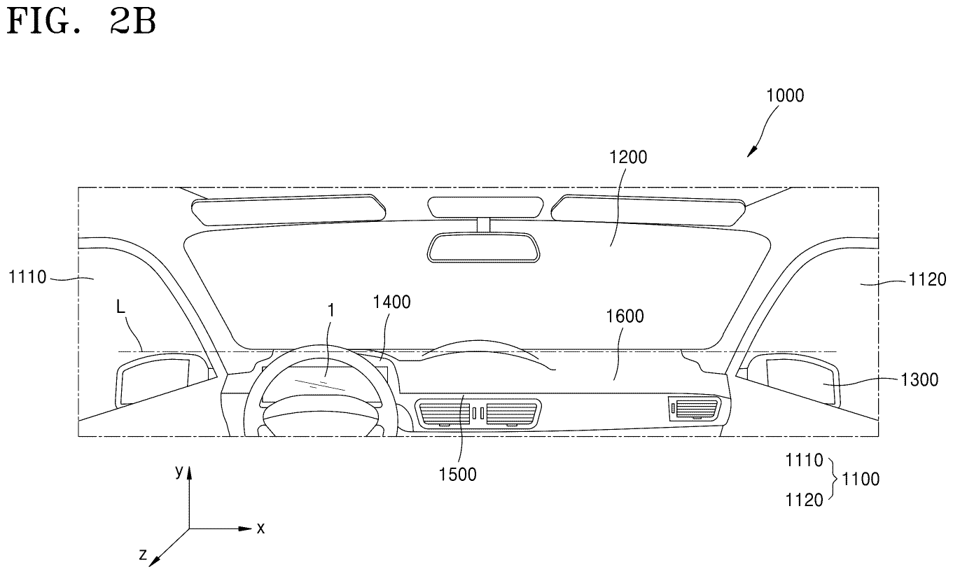

FIG. 1 is a diagram schematically illustrating the exterior of a vehicle 1000 according to an embodiment. FIGS. 2A and 2B are diagrams schematically illustrating the interior of the vehicle 1000 according to an embodiment.

Referring to FIGS. 1, 2A, and 2B, the vehicle 1000 may be any of various devices that move a transport object such as, for example, a human, object, or animal, from a departure point to a destination. The vehicle 1000 may include a vehicle traveling on a road or a track, a ship moving on the sea or a river, an airplane flying in the sky by using the action of air, or other suitable vehicle supportive of aspects of the present disclosure.

The vehicle 1000 may travel on a road or a track. The vehicle 1000 may move in a certain direction according to rotation of at least one wheel. For example, the vehicle 1000 may be a three-wheeled vehicle, a four-wheeled vehicle, construction equipment, a two-wheeled vehicle, a motor vehicle, a bicycle, or a train running on a track.

The vehicle 1000 may include a body having an interior and an exterior, and a chassis, which is a remaining part excluding the body and in which mechanical devices associated with driving are installed. The exterior of the body may include a front panel, a bonnet, a roof panel, a rear panel, a trunk, and a filler provided at boundaries between doors. The chassis of the vehicle 1000 may include power generation devices, power transmission devices, running devices, steering devices, braking devices, suspension devices, transmission devices, fuel devices, front, rear, left, and right wheels, or other components of the vehicle 1000.

The vehicle 1000 may include a side window glass 1100, a front window glass 1200, a side mirror 1300, a cluster 1400, a center fascia 1500, a passenger dashboard 1600, and a display device 1.

The side window glass 1100 and the front window glass 1200 may be partitioned by a filler portion arranged between the side window glass 1100 and the front window glass 1200.

The side window glass 1100 may be installed on a side of the vehicle 1000. In an embodiment, the side window glass 1100 may be installed on a door of the vehicle 1000. The side window glass 1100 may include a plurality of pieces of side window glass 1100, which may face each other. In an embodiment, the side window glass 1100 may include a first side window glass 1110 and a second side window glass 1120. The first side window glass 1110 may be arranged adjacent to the cluster 1400. The second side window glass 1120 may be arranged adjacent to the passenger dashboard 1600.

The pieces of side window glass 1100 may be spaced apart from each other in a first direction (e.g., an x direction). For example, the first side window glass 1110 and the second side window glass 1120 may be spaced apart from each other in the x direction. In other words, an imaginary connection line L connecting the pieces of side window glass 1100 may extend in the first direction (e.g., the x direction).

The front window glass 1200 may be installed at the front of the vehicle 1000. The front window glass 1200 may be arranged adjacent to pieces of side window glass 1100 that face each other.

The side mirror 1300 may provide a view of the rear of the vehicle 1000. The side mirror 1300 may be installed on the exterior of the body. The side mirror 1300 may include a plurality of side mirrors. One of the plurality of side mirrors 1300 may be arranged outside the first side window glass 1110. Another one of the plurality of side mirrors 1300 may be arranged outside the second side window glass 1120.

The cluster 1400 may be positioned in front of a steering wheel. The cluster 1400 may have arranged therein a tachometer, a speedometer, a coolant temperature gauge, a fuel gauge turn indicator light, a high beam indicator light, a warning light, a seat belt warning light, an odometer, an automatic shift selection lever indicator light, a door open warning light, an engine oil warning light, and/or a low fuel warning light.

The center fascia 1500 may include an audio device, an air conditioning device, and a control panel with a plurality of buttons for adjusting a seat heater. The center fascia 1500 may be arranged on one side of the cluster 1400.

The passenger dashboard 1600 may be spaced apart from the cluster 1400, with the center fascia 1500 between the cluster 1400 and the passenger dashboard 1600. In an embodiment, the cluster 1400 may be arranged to correspond to a driver's seat (not illustrated), and the passenger dashboard 1600 may be arranged to correspond to a passenger seat (not illustrated). In an embodiment, the cluster 1400 may be adjacent to the first side window glass 1110, and the passenger dashboard 1600 may be adjacent to the second side window glass 1120.

The display device 1 may be arranged inside the vehicle 1000. The display device 1 may be arranged between the pieces of side window glass 1100. The display device 1 may display an image. In an embodiment, the display device 1 may be arranged on at least one of the cluster 1400, the center fascia 1500, and the passenger dashboard 1600.

The display device 1 may include liquid crystal displays, electrophoretic displays, organic light-emitting displays, inorganic light-emitting displays, field emission displays, surface-conduction electron-emitter displays, quantum dot displays, plasma displays, cathode ray displays, or other displays. Hereinbelow, an organic light-emitting display is described as an example of the display device 1 according to an embodiment, but display devices of various types as described herein may be used in one or more embodiments.

Referring to FIG. 2A, the display device 1 may be disposed on the center fascia 1500. In an embodiment, the display device 1 may display navigation information. In an embodiment, the display device 1 may display information about audio, video, or vehicle settings.

Light emitted from the display device 1 may travel in a specific direction. For example, the light emitted from the display device 1 may travel toward the driver's seat (not illustrated). The light emitted from the display device 1 may travel toward the passenger seat (not illustrated). The light emitted from the display device 1 may not travel to the front window glass 1200. Alternatively, the light emitted from the display device 1 may travel to the front window glass 1200 at a relatively small ratio (e.g., according to a relatively small viewing angle). In an example in which the light emitted from the display device 1 travels toward the front window glass 1200, the light emitted from the display device 1 may be reflected from the front window glass 1200 and may reach the driver's seat. Accordingly, the driver may recognize an image of the display device 1 on the front window glass 1200, but may be unable to recognize an object in front of the vehicle 1000, which is unsafe during driving. In the present embodiment, because a top-bottom viewing angle of the display device 1 disposed on the center fascia 1500 is limited, the light emitted from the display device 1 and traveling toward the front window glass 1200 may be minimized or reduced.

Referring to FIG. 2B, the display device 1 may be disposed on the cluster 1400. In this case, the cluster 1400 may express driving information or other information by the display device 1. In other words, the cluster 1400 may be implemented digitally. The cluster 1400 that is digital may display vehicle information and driving information as images. For example, tachometer needles and gauges and various warning light icons may be displayed by digital signals.

Light emitted from the display device 1 may travel in a specific direction. For example, the light emitted from the display device 1 may travel toward the driver's seat (not illustrated). In an embodiment, the light emitted from the display device 1 may not travel to the front window glass 1200. Alternatively, the light emitted from the display device 1 may travel to the front window glass 1200 at a relatively small ratio. In an example in which the light emitted from the display device 1 travels toward the front window glass 1200, the light emitted from the display device 1 may be reflected from the front window glass 1200 and may reach the driver's seat. Accordingly, the driver may recognize an image of the display device 1 on the front window glass 1200, which may cause safety problems during driving. In the present embodiment, because a top-bottom viewing angle of the display device 1 disposed on the cluster 1400 is limited, the light emitted from the display device 1 and traveling toward the front window glass 1200 may be minimized or reduced.

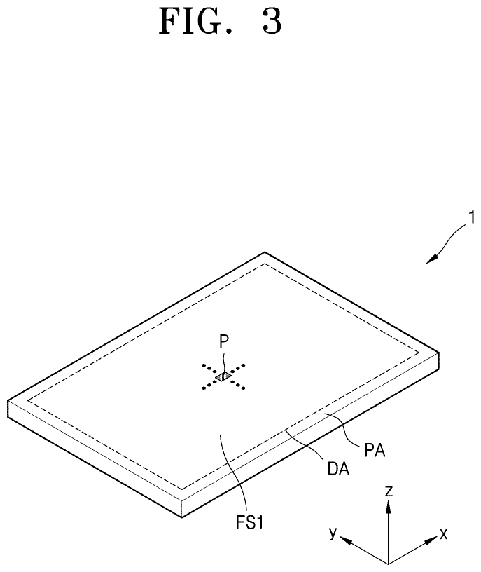

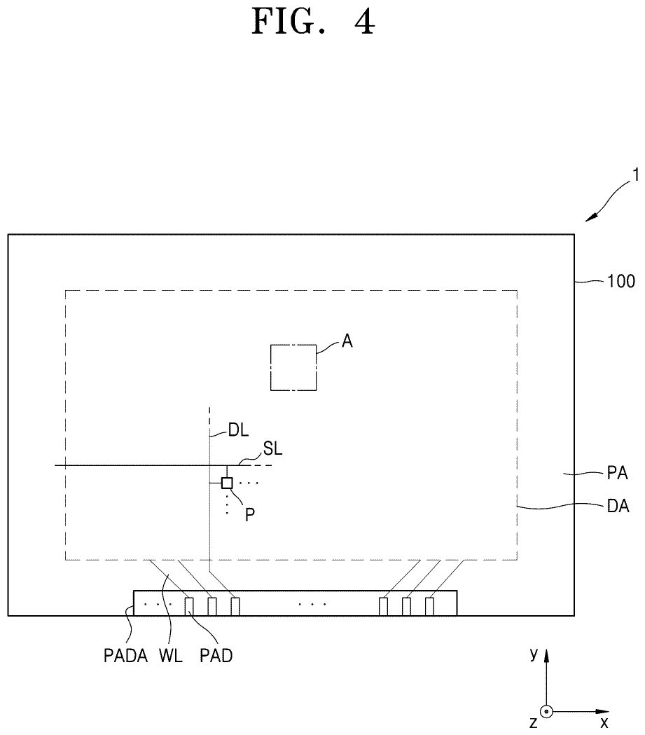

FIG. 3 is a perspective view schematically illustrating the display device 1 according to an embodiment. FIG. 4 is a plan view schematically illustrating the display device 1 according to an embodiment.

Referring to FIGS. 3 and 4, the display device 1 may include a display area DA and a peripheral area PA. The display device 1 may include a substrate 100 and a multi-layer structure that is on the substrate 100. The display area DA and the peripheral area PA may be defined in the substrate 100 and/or in the multi-layer structure. For example, the display area DA and the peripheral area PA may be defined in the substrate 100. In other words, the substrate 100 may include the display area DA and the peripheral area PA.

A plurality of sub-pixels P may be arranged in the display area DA. In an embodiment, the sub-pixels P may be disposed on a front surface FS1 of the display device 1.

The plurality of sub-pixels P may be arranged in the display area DA and may display an image. The sub-pixel P may be implemented as an emission element. Light emitted from the sub-pixel P may travel in one specific direction from the front surface FS1 of the display device 1. The light emitted from the sub-pixel P may not travel in another specific direction from the front surface FS1 of the display device 1. In an embodiment, the light emitted from the sub-pixel P may travel in a direction perpendicular to the front surface FS1 of the display device 1 (e.g., a z direction). The light emitted from the sub-pixel P may travel in a direction oblique to the front surface FS1 of the display device 1 (e.g., a direction crossing the z direction). In an embodiment, the light emitted from the sub-pixel P may not have components in the first direction (e.g., the x direction) and/or in a second direction (e.g., a y direction).

The sub-pixel P may emit one of red, green, and blue light by using an emission element. In an embodiment, the sub-pixel P may emit one of red, green, blue, and white light by using the emission element. The sub-pixel P may be defined as an emission area of an emission element that emits one of red, green, blue, and white light.

The sub-pixel P is an emission element capable of emitting light of a certain color and may include a light-emitting diode. The light-emitting diode may include an organic light-emitting diode including an organic material as an emission layer. Alternatively, the light-emitting diode may include an inorganic light-emitting diode. Alternatively, the light-emitting diode may include quantum dots as an emission layer. In an embodiment, a size of the light-emitting diode may be micro scale or nano scale. For example, the light-emitting diode may be a micro-light-emitting diode. Alternatively, the light-emitting diode may be a nano-light-emitting diode. The nano-light-emitting diode may include gallium nitride (GaN). In an embodiment, a color conversion layer may be disposed on the nano-light-emitting diode. The color conversion layer may include quantum dots. Hereinbelow, for convenience of description, a case in which the light-emitting diode includes an organic light-emitting diode is mainly described in detail.

A pixel circuit for driving the sub-pixel P may be connected to a scan line SL that extends in the first direction (e.g., the x direction) and a data line DL that extends in the second direction (e.g., the y direction).

The peripheral area PA may be an area in which an image is not provided. The peripheral area PA may be arranged outside the display area DA. The peripheral area PA may at least partially surround the display area DA. In an embodiment, the peripheral area PA may entirely surround the display area DA. A scan driver (not illustrated) for providing a scan signal to each sub-pixel P may be arranged in the peripheral area PA. A data driver (not illustrated) for providing a data signal to the sub-pixel P may be arranged in the peripheral area PA. The peripheral area PA may include a pad area PADA. In an embodiment, pads PAD may be arranged in the pad area PADA. The pads PAD may be exposed by not being covered by an insulating layer and may be electrically connected to a printed circuit board or a driver integrated circuit (IC).

A plurality of lines WL may be arranged in the peripheral area PA. The plurality of lines WL may transfer, through the pads PAD, signals and/or voltages received from the printed circuit board or the driver IC to the pixel circuit configured to drive the sub-pixel P arranged in the display area DA.

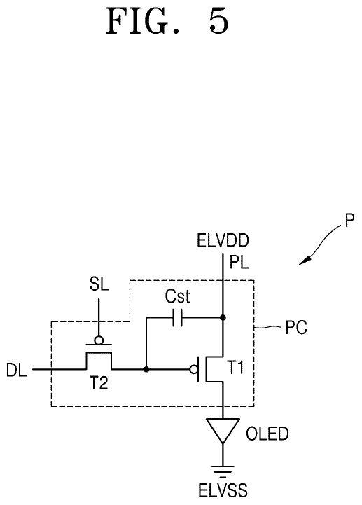

FIG. 5 is an equivalent circuit diagram schematically illustrating the sub-pixel P according to an embodiment.

Referring to FIG. 5, the sub-pixel P may include a pixel circuit PC and an organic light-emitting diode OLED that is an emission element. The pixel circuit PC may include a driving transistor T1, a switching transistor T2, and a storage capacitor Cst. The sub-pixel P may emit, for example, one of red, green, and blue light, or one of red, green, blue, and white light through the organic light-emitting diode OLED.

The switching transistor T2 may be connected to the scan line SL and the data line DL and may transfer a data signal or data voltage received via the data line DL to the driving transistor T1 based on a scan signal or switching voltage received via the scan line SL. The storage capacitor Cst may be connected to the switching transistor T2 and a driving voltage line PL and may store a voltage corresponding to a difference between a voltage received from the switching transistor T2 and a first power voltage ELVDD that is supplied to the driving voltage line PL.

The driving transistor T1 may be connected to the driving voltage line PL and the storage capacitor Cst and may control a driving current flowing through the organic light-emitting diode OLED from the driving voltage line PL to correspond to a voltage value stored in the storage capacitor Cst. The organic light-emitting diode OLED may emit light having a certain luminance according to the driving current. A common electrode (e.g., a cathode) of the organic light-emitting diode OLED may receive a second power voltage ELVSS.

In FIG. 5, the pixel circuit PC includes two transistors and one storage capacitor. However, one or more embodiments are not limited thereto. In another embodiment, the pixel circuit PC may include three or more transistors. In another embodiment, the pixel circuit PC may include two or more storage capacitors.

In an embodiment, each of the driving transistor T1 and the switching transistor T2 may be provided as a p-channel metal-oxide-semiconductor field-effect transistor (MOSFET; PMOS) or as an n-channel MOSFET (NMOS). Alternatively, some of a plurality of transistors included in the pixel circuit PC may be provided as PMOS transistors, and the remaining portion may be provided as NMOS transistors.

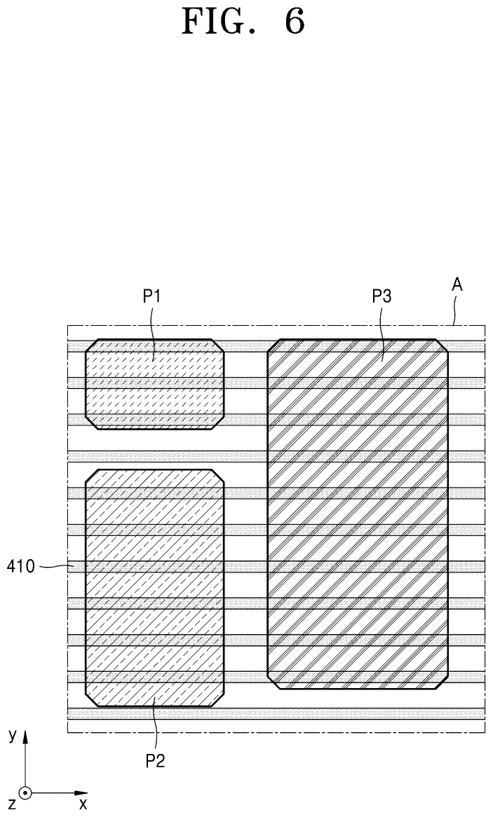

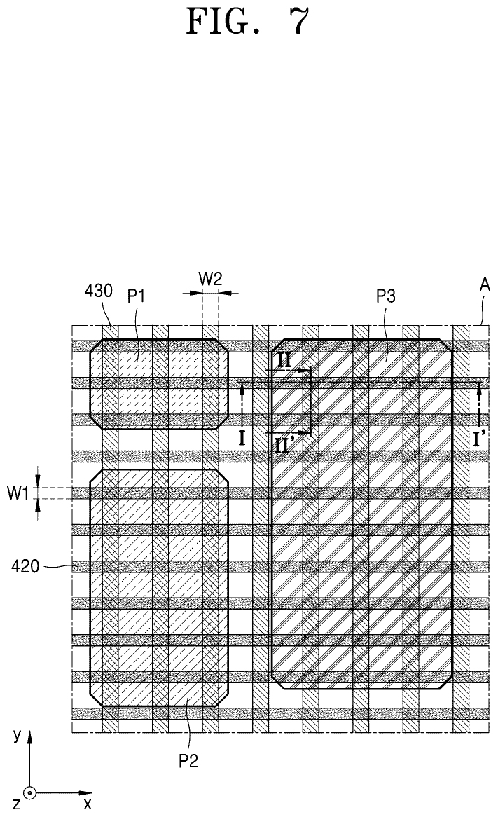

FIGS. 6 and 7 are enlarged views of some elements of the display device 1 in enlarged region A in FIG. 4, according to an embodiment. FIG. 6 illustrates an arrangement of an electrode line 410 on an x-y plane, and FIG. 7 illustrates an arrangement of a first light-shielding line 420 and a second light-shielding line 430 on an x-y plane corresponding to the x-y plane of FIG. 6. FIG. 7 illustrates the second light-shielding line 430 in a case in which no voltage is applied to the electrode line 410 and an electrode layer 440 described herein.

Referring to FIGS. 6 and 7, the display device 1 may include first to third sub-pixels P1, P2, and P3 in the display area DA. The first sub-pixel P1, the second sub-pixel P2, and the third sub-pixel P3 may be respectively defined by emission areas of light-emitting elements of the first sub-pixel P1, the second sub-pixel P2, and the third sub-pixel P3.

The first sub-pixel P1, the second sub-pixel P2, and the third sub-pixel P3 may emit light in different wavelength bands from each other. In other words, the first sub-pixel P1, the second sub-pixel P2, and the third sub-pixel P3 may emit light of different colors from each other. The first sub-pixel P1 may emit light in a first wavelength band. For example, the first sub-pixel P1 may emit light of a wavelength ranging from 630 nm to 780 nm. The second sub-pixel P2 may emit light in a second wavelength band. For example, the second sub-pixel P2 may emit light of a wavelength ranging from 495 nm to 570 nm. The third sub-pixel P3 may emit light in a third wavelength band. For example, the third sub-pixel P3 may emit light of a wavelength ranging from 450 nm to 495 nm.

In an embodiment, the first sub-pixel P1, the second sub-pixel P2, and the third sub-pixel P3 may have a rectangular shape from among polygonal shapes. Herein, polygons or rectangles also include shapes with rounded corners. In other words, the first sub-pixel P1, the second sub-pixel P2, and the third sub-pixel P3 may have a rectangular shape with round corners. In another embodiment, the first sub-pixel P1, the second sub-pixel P2, and the third sub-pixel P3 may have a circular or elliptical shape.

In an embodiment, sizes of the first sub-pixel P1, the second sub-pixel P2, and the third sub-pixel P3 may be different from each other. For example, an area of the first sub-pixel P1 may be less than an area of each of the second sub-pixel P2 and the third sub-pixel P3, and the area of the third sub-pixel P3 may be greater than the area of the second sub-pixel P2. However, one or more embodiments are not limited thereto. Shapes and sizes of the first to third sub-pixels P1, P2, and P3 are not limited to those illustrated and may vary.

The first sub-pixel P1 and the second sub-pixel P2 may each be provided in plurality and may be repeatedly arranged to be spaced apart from each other in the second direction (e.g., the y direction). The third sub-pixel P3 may be provided in plurality and may be arranged spaced apart from each other in the second direction (e.g., the y direction). A pixel column formed by the first sub-pixel P1 and the second sub-pixel P2 that are alternately arranged in the second direction (e.g., the y direction) and a pixel column formed by the plurality of third sub-pixels P3 arranged in the second direction (e.g., the y direction) may be repeatedly arranged to be spaced apart from each other in the first direction (e.g., the x direction). However, one or more embodiments are not limited thereto. For example, the first to third sub-pixels P1, P2, and P3 may be arranged in various pixel array structures such as, for example, a PenTile™ structure, a stripe structure, a mosaic structure, or a delta structure.

As illustrated in FIG. 6, the display device 1 may include a plurality of electrode lines 410 on the first sub-pixel P1, the second sub-pixel P2, and the third sub-pixel P3. Each of the electrode lines 410 may extend in the first direction (e.g., the x direction). The electrode line 410 may be arranged spaced apart from each other in the second direction (e.g., the y direction), which crosses the first direction (e.g., the x direction).

As illustrated in FIG. 7, the display device 1 may include the first light-shielding lines 420 on the electrode lines 410, and may include the second light-shielding lines 430 on the first light-shielding lines 420.

The first light-shielding lines 420 may include a light-shielding material. Because the first light-shielding lines 420 includes the light-shielding material, the first light-shielding lines 420 may block or absorb light. For example, the first light-shielding lines 420 may include a black matrix. For example, the first light-shielding lines 420 may include black dye such as, for example, carbon black.

Each of the first light-shielding lines 420 may extend in the first direction (e.g., the x direction). The first light-shielding lines 420 may be arranged to overlap the electrode lines 410, respectively. The first light-shielding lines 420 may be arranged spaced apart from each other in the second direction (e.g., the y direction).

In the display device 1 according to an embodiment, when each of the first light-shielding lines 420 is arranged to extend in the first direction (e.g., the x direction), traveling of light emitted from the first to third sub-pixels P1, P2, and P3 in the second direction (e.g., the y direction) may be prevented or reduced. Accordingly, as described with reference to FIGS. 2A and 2B, the traveling of the light emitted from the display device 1 toward the front window glass 1200 of the vehicle 1000 may be prevented or reduced.

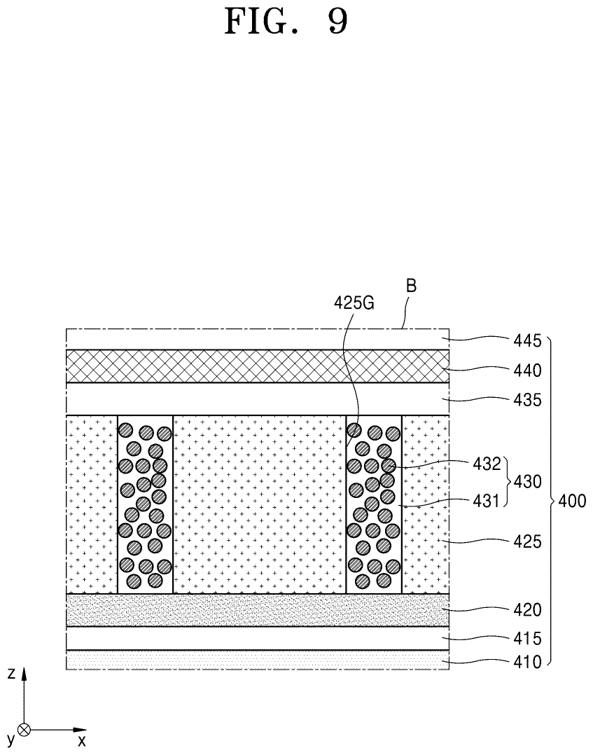

The second light-shielding lines 430 may include an electrophoretic solution including light-shielding particles 432 (see FIG. 9). Because the second light-shielding lines 430 include the light-shielding particles 432, the second light-shielding lines 430 may block or absorb light. The light-shielding particles 432 provided in the second light-shielding line 430 may have conductivity. Accordingly, because the light-shielding particles 432 in the second light-shielding lines 430 move depending on whether a voltage is applied, light transmittance of the second light-shielding lines 430 may vary.

The second light-shielding lines 430 may be arranged such that the second light-shielding lines 430 cross the first light-shielding lines 420. For example, the second light-shielding lines 430 may extend in a direction perpendicular to the first light-shielding lines 420. For example, each of the second light-shielding lines 430 may extend in the second direction (e.g., the y direction). The second light-shielding lines 430 may be arranged such that the second light-shielding lines 430 cross the electrode lines 410. For example, the second light-shielding lines 430 may extend in a direction perpendicular to the electrode lines 410. The second light-shielding lines 430 may be arranged spaced apart from each other in the first direction (e.g., the x direction).

When no voltage is applied to the second light-shielding lines 430, the light-shielding particles 432 (see FIG. 9) included in the second light-shielding lines 430 may be dispersed in the form of a line that extends in the second direction (e.g., the y direction). Accordingly, due to the second light-shielding lines 430, the traveling of the light emitted from the first to third sub-pixels P1, P2, and P3 in the first direction (e.g., the x direction) may be prevented or reduced. Thus, when no voltage is applied to the second light-shielding lines 430, since the left-right viewing angle of the display device 1 of the vehicle 1000 (see FIGS. 1 to 2B) is limited, confusion in the field of view between the driver's seat and the passenger seat while driving the vehicle 1000 may be prevented or reduced.

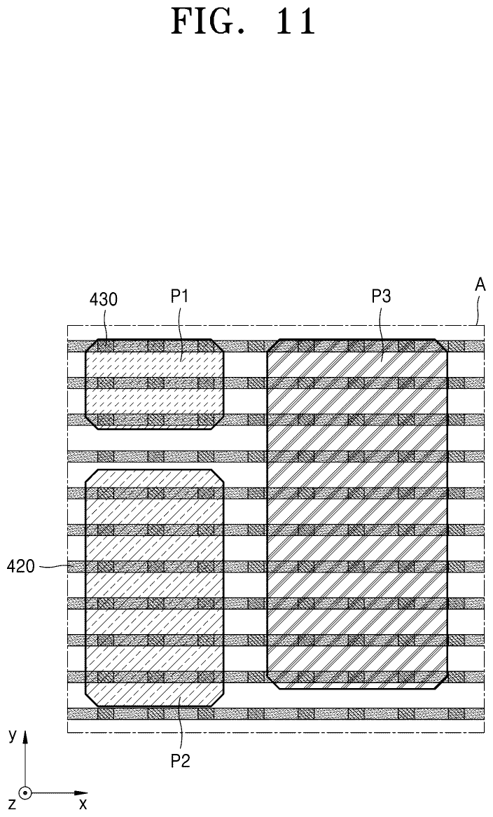

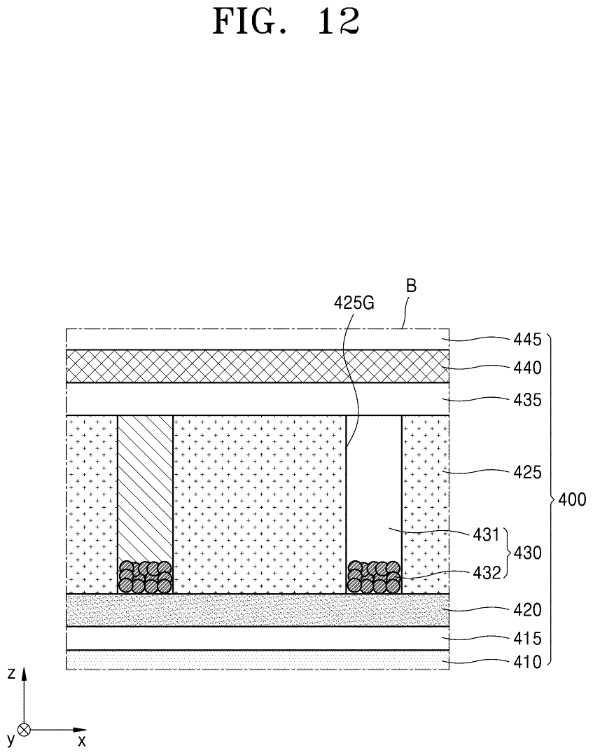

Embodiments of the present disclosure support, depending on the user's needs or preferences, applying a voltage to the second light-shielding lines 430, as described herein with reference to FIGS. 11 and 12. Accordingly, for example, based on the applied voltage, an optical path in the first direction (e.g., the x direction) is not limited, such that an image may be recognized from both the left and right sides.

A width W2 of the second light-shielding line 430 in the first direction (e.g., the x direction) may be greater than a width W1 of the first light-shielding line 420 in the second direction (e.g., the y direction).

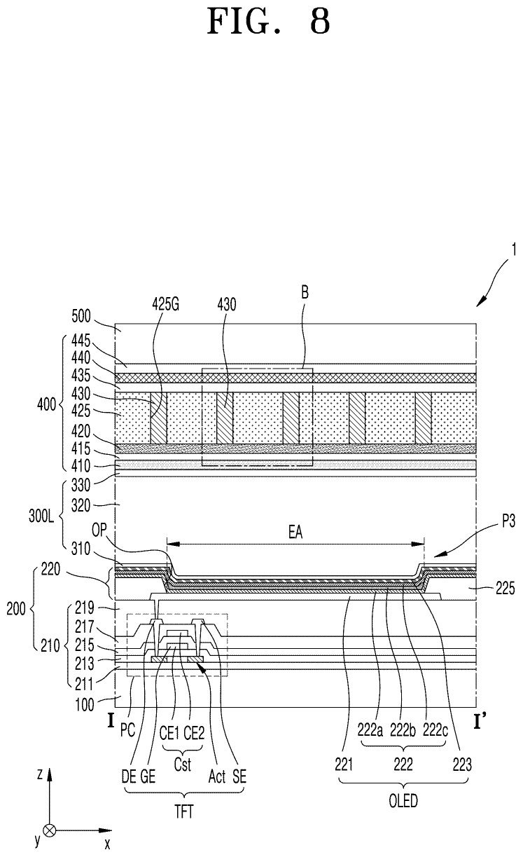

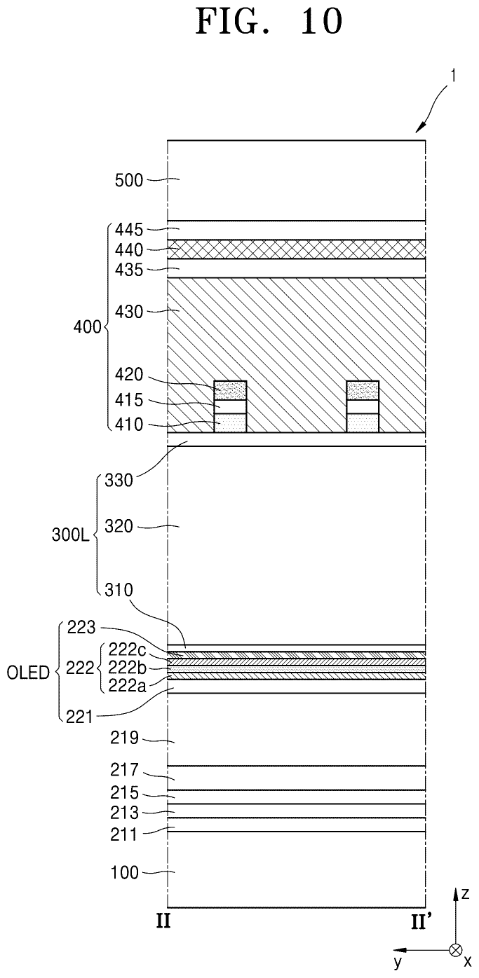

FIG. 8 is a cross-sectional view schematically illustrating the display device 1 in FIG. 7, taken along line I-I in FIG. 7, according to an embodiment. FIG. 9 is an enlarged view of region B in FIG. 8 in a case where no voltage is applied to the electrode line 410 and the electrode layer 440, according to an embodiment. FIG. 10 is a cross-sectional view schematically illustrating the display device 1 in FIG. 7, taken along line II-II in FIG. 7, according to an embodiment.

Referring to FIGS. 8 to 10, the display device 1 may include the substrate 100, a display layer 200 that is on the substrate 100, an encapsulation layer 300L that is on the display layer 200, an optical path control layer 400 that is on the encapsulation layer 300L, and a cover window 500 that is on the optical path control layer 400.

The substrate 100 may include glass or polymer resin such as, for example, polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may have a multi-layer structure that includes a base layer including the polymer resin described herein and a barrier layer (not illustrated). The substrate 100 including the polymer resin may have flexible, rollable, or bendable characteristics.

The display layer 200 may be disposed on the substrate 100. The display layer 200 may include a pixel circuit layer 210 and an emission element layer 220. The pixel circuit layer 210 may include a buffer layer 211, a first gate insulating layer 213, a second gate insulating layer 215, an interlayer insulating layer 217, an organic insulating layer 219, and a pixel circuit PC. The pixel circuit PC may include a thin-film transistor TFT and a storage capacitor Cst. The thin-film transistor TFT may include a semiconductor layer Act, a gate electrode GE, a source electrode SE, and a drain electrode DE.

The buffer layer 211 may be disposed on the substrate 100. The buffer layer 211 may include an inorganic insulating material such as, for example, silicon nitride (SiNₓ), silicon oxynitride (SiON), and silicon oxide (SiO₂), and may have a layer or layers including the inorganic insulating materials described herein.

The semiconductor layer Act may be disposed on the buffer layer 211. The semiconductor layer Act may include polysilicon. Alternatively, the semiconductor layer Act may include amorphous silicon, an oxide semiconductor, an organic semiconductor, or the like. The semiconductor layer Act may include a channel region, and a drain region and a source region that are respectively arranged at opposite sides of the channel region.

The first gate insulating layer 213 may be disposed on the semiconductor layer Act and the buffer layer 211. The first gate insulating layer 213 may include an inorganic insulating material such as, for example, SiO₂, SiNₓ, SiON, aluminum oxide (Al₂O₃), titanium oxide (TiO₂), tantalum oxide (Ta₂O₅), hafnium oxide (HfO₂), or zinc oxide (ZnOₓ). ZnOx may include zinc oxide (ZnO) and/or zinc peroxide (ZnO₂).

The gate electrode GE may be disposed on the first gate insulating layer 213. The gate electrode GE may overlap the channel region. The gate electrode GE may include a low-resistance metal material. The gate electrode GE may include a conductive material, including molybdenum (Mo), aluminum (Al), copper (Cu), titanium (Ti), or the like, and may be provided as a layer or layers including the materials described herein.

The second gate insulating layer 215 may be disposed on the gate electrode GE and the first gate insulating layer 213. Similar to the first gate insulating layer 213, the second gate insulating layer 215 may include an inorganic insulating material such as, for example, SiO₂, SiNₓ, SiON, Al₂O₃, TiO₂, Ta₂O₅, HfO₂, or ZnOₓ.

An upper electrode CE2 of the storage capacitor Cst may be disposed on the second gate insulating layer 215. The upper electrode CE2 may overlap the gate electrode GE thereunder. In this case, the gate electrode GE and the upper electrode CE2 overlapping each other, with the second gate insulating layer 215 between the gate electrode GE and the upper electrode CE2, may constitute the storage capacitor Cst. In other words, the gate electrode GE may function as a lower electrode CE1 of the storage capacitor Cst. In an embodiment, the storage capacitor Cst and the thin-film transistor TFT may overlap each other. In some embodiments, the storage capacitor Cst may not overlap the thin-film transistor TFT. The upper electrode CE2 may include Al, platinum (Pt), palladium (Pd), silver (Ag), magnesium (Mg), gold (Au), nickel (Ni), neodymium (Nd), iridium (Ir), chrome (Cr), calcium (Ca), Mo, Ti, tungsten (W), and/or Cu, and may be a layer or layers of the materials described herein.

The interlayer insulating layer 217 may be disposed on the upper electrode CE2 and the second gate insulating layer 215. The interlayer insulating layer 217 may include SiO₂, SiNₓ, SiON, Al₂O₃, TiO₂, Ta₂O₅, HfO₂, or ZnOₓ. The interlayer insulating layer 217 may be a layer or layers including the inorganic insulating materials described herein.

The drain electrode DE and the source electrode SE may be disposed on the interlayer insulating layer 217. Each of the drain electrode DE and the source electrode SE may be electrically connected to the semiconductor layer Act. The drain electrode DE and the source electrode SE may include a material having high conductivity. The drain electrode DE and the source electrode SE may include a conductive material, including Mo, Al, Cu, Ti, or the like, and may be provided as a layer or layers including the materials described herein. In an embodiment, the drain electrode DE and the source electrode SE may have a multi-layer structure of Ti/Al/Ti.

The organic insulating layer 219 may be disposed on the drain electrode DE, the source electrode SE, and the interlayer insulating layer 217. The organic insulating layer 219 may include an organic insulating material such as, for example, general-purpose polymers such as, for example, polymethylmethacrylate (PMMA) or polystyrene (PS), polymer derivatives having a phenol-based group, acryl-based polymers, imide-based polymers, aryl ether-based polymers, amide-based polymers, fluorine-based polymers, p-xylene-based polymers, vinyl alcohol-based polymers, and any blends thereof. In some embodiment, the organic insulating layer 219 may include a first organic insulating layer and a second organic insulating layer.

The emission element layer 220 may be disposed on the pixel circuit layer 210. The emission element layer 220 may be disposed on the organic insulating layer 219. The emission element layer 220 may include an emission element that implements a sub-pixel. The emission element may be the organic light-emitting diode OLED. The emission element layer 220 may include a first organic light-emitting diode, a second organic light-emitting diode, and a third organic light-emitting diode. For example, in FIG. 8, the organic light-emitting diode OLED may implement the third sub-pixel P3.

The organic light-emitting diode OLED may include a pixel electrode 221, an intermediate layer 222, and an opposite electrode 223. The pixel electrode 221 may be electrically connected to the thin-film transistor TFT through a contact hole defined in the organic insulating layer 219. The pixel electrode 221 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 221 may include a reflective film including Ag Mg, Al, Pt, Pd, Au, Ni, Nd, Ir, Cr, or any compounds thereof. In another embodiment, the pixel electrode 221 may further include a film formed of ITO, IZO, ZnO, or In₂O₃, over/under the reflective film described herein. For example, the pixel electrode 221 may have a multi-layer structure of ITO/Ag/ITO.

A pixel-defining layer 225 may cover an edge of the pixel electrode 221. The pixel-defining layer 225 may have an opening OP. The opening OP may expose a central portion of the pixel electrode 221. The opening OP defined in the pixel-defining layer 225 may define an emission area EA of light emitted from the organic light-emitting diode OLED. For example, the emission area EA may be defined as a size of the opening OP defined in the pixel-defining layer 225. In an embodiment, the pixel-defining layer 225 may include an organic material and/or an inorganic material. In an embodiment, the pixel-defining layer 225 may be transparent. In some embodiments, the pixel-defining layer 225 may include black matrix. In this case, the pixel-defining layer 225 may be opaque.

The intermediate layer 222 may include a first functional layer 222a, an emission layer 222b, and a second functional layer 222c. The emission layer 222b may include a polymer or low-molecular weight organic material that emits light of a certain color. In an embodiment, at least one of the first functional layer 222a and the second functional layer 222c may be a common layer arranged throughout a display area. For example, the first functional layer 222a may include a hole transport layer, or the first functional layer 222a may include a hole transport layer and a hole injection layer. The second functional layer 222c may include an electron transport layer or an electron injection layer. In some embodiments, the second functional layer 222c may be omitted.

The opposite electrode 223 may be disposed on the emission layer 222b. The opposite electrode 223 may include a conductive material having a low work function. For example, the opposite electrode 223 may include a (semi-)transparent layer including Ag, Mg, Al, Pt, Pd, Au, Ni, Nd, Ir, Cr, Li, Ca, or any alloys thereof. Alternatively, the opposite electrode 223 may further include a layer including ITO, IZO, ZnO, or In₂O₃, over the (semi-)transparent layer including the materials described herein.

In some embodiments, a capping layer (not illustrated) may be further disposed on the opposite electrode 223. The capping layer may include lithium fluoride (LiF), an inorganic material, and/or an organic material.

The encapsulation layer 300L may be disposed on the display layer 200. The encapsulation layer 300L may seal emission elements positioned on the display layer 200. The encapsulation layer 300L may include at least one inorganic encapsulation layer and at least one organic encapsulation layer. For example, the inorganic encapsulation layer may include one or more inorganic materials from among Al₂O₃, TiO₂, Ta₂O₅, ZnO, SiO₂, SiNₓ, and SiON. For example, the organic encapsulation layer may include a polymer-based material. For example, the polymer-based material may include acryl-based resin, epoxy-based resin, polyimide, and polyethylene. In an embodiment, the at least one organic encapsulation layer may include acrylate. In an embodiment, the encapsulation layer 300L may include, as illustrated in FIGS. 8 and 10, a first inorganic encapsulation layer 310, an organic encapsulation layer 320 that is on the first inorganic encapsulation layer 310, and a second inorganic encapsulation layer 330 that is on the organic encapsulation layer 320.

The optical path control layer 400 may be disposed on the encapsulation layer 300L. The optical path control layer 400 may include electrode lines 410, first light-shielding lines 420, an organic layer 425, second light-shielding lines 430, and an electrode layer 440.

The electrode lines 410 may be disposed on the encapsulation layer 300L. The electrode lines 410 may include a conductive material. In an embodiment, the electrode lines 410 may include a transparent conductive material. For example, the electrode lines 410 may include a transparent conductive oxide such as, for example, ITO and IZO.

In an embodiment, the optical path control layer 400 may further include a first passivation layer 415 between the electrode lines 410 and the first light-shielding lines 420. The first passivation layer 415 may be disposed on the electrode lines 410. The first passivation layer 415 may have a plurality of passivation patterns, and the passivation patterns may be arranged to overlap the electrode lines 410. The passivation patterns may extend in the first direction (e.g., the x direction) to overlap the electrode lines 410. The first passivation layer 415 may include, for example, an inorganic material.

The first light-shielding lines 420 may be disposed on the electrode lines 410. In an embodiment, the first light-shielding lines 420 may be disposed on the first passivation layer 415. The first light-shielding lines 420 may be arranged between the electrode lines 410 and the electrode layer 440 described herein. Although the first light-shielding lines 420 are illustrated as a single layer, one or more embodiments are not limited thereto. For example, the first light-shielding lines 420 may include one or more layers to adjust a light blocking rate.

The organic layer 425 may be disposed on the first light-shielding lines 420. The organic layer 425 may include a plurality of grooves 425G that extend in the second direction (e.g., the y direction). In an embodiment, the groove 425G may be a through-hole passing through the organic layer 425. In other words, a portion of an upper surface of the first light-shielding line 420 may be exposed by the groove 425G of the organic layer 425. In an embodiment, a side surface of the organic layer 425 exposed by the groove 425G may be substantially perpendicular to the upper surfaces of the first light-shielding lines 420. In an embodiment, a depth of the groove 425G of the organic layer 425 may be equal to a thickness of the organic layer 425. The organic layer 425 may include an organic material.

The second light-shielding lines 430 may be disposed on the first light-shielding lines 420. The second light-shielding lines 430 may be arranged between the electrode lines 410 and the electrode layer 440 described herein. In an embodiment, the groove 425G passes through the organic layer 425, such that the second light-shielding lines 430 arranged in the grooves 425G may be in contact with the first light-shielding lines 420.

The second light-shielding lines 430 may be respectively arranged in the grooves 425G of the organic layer 425. The second light-shielding lines 430 may be formed by injecting an electrophoretic solution into the grooves 425G of the organic layer 425. The electrophoretic solution may include, as illustrated in FIG. 9, a transparent fluid 431 and light-shielding particles 432 dispersed in the transparent fluid 431. In other words, the second light-shielding lines 430 may include the transparent fluid 431 and the light-shielding particles 432. The light-shielding particles 432 may have electrophoretic properties and light-blocking (or light-absorbing) properties. For example, the light-shielding particles 432 may include carbon black, but are not limited thereto. The light-shielding particles 432 may move freely in the transparent fluid 431. In an example in which a voltage is applied between the electrode lines 410 and the electrode layer 440, the light-shielding particles 432 have conductivity and may move toward the electrode lines 410 in the transparent fluid 431. The transparent fluid 431 may transmit light, flow within the groove 425G, and facilitate movement of the light-shielding particles 432.

Referring to FIGS. 7 to 9, when no voltage is applied between the e and the electrode layer 440, because the light-shielding particles 432 included in the second light-shielding lines 430 are dispersed in the groove 425G, the light-shielding particles 432 may be dispersed in the form of a line that extends in the second direction (e.g., the y direction). Accordingly, the second light-shielding lines 430 including the light-shielding particles 432 may extend in the second direction (e.g., the y direction).

In an embodiment, the optical path control layer 400 may further include a capping layer 435 between the second light-shielding lines 430 and the electrode layer 440. For example, the capping layer 435 may include an organic material or an inorganic material. The capping layer 435 may prevent the electrophoretic solution injected into the groove 425G from overflowing.

The electrode layer 440 may be disposed on the second light-shielding lines 430. The electrode layer 440 may face the electrode lines 410, with the second light-shielding lines 430 between the electrode layer 440 and the electrode lines 410. Light transmittance of the second light-shielding lines 430 may vary depending on the voltage applied between the electrode lines 410 and the electrode layer 440. In an embodiment, the electrode layer 440 may be disposed on the capping layer 435. In an embodiment, the electrode layer 440 may be in the shape of a single plate disposed on the x-y plane. The electrode layer 440 may include a conductive material. In an embodiment, the electrode layer 440 may include a transparent conductive material. For example, the electrode layer 440 may include a transparent conductive oxide such as, for example, ITO and IZO.

In an embodiment, the optical path control layer 400 may further include a second passivation layer 445 on the electrode layer 440. The second passivation layer 445 may include, for example, an inorganic material.

The cover window 500 may be disposed on the optical path control layer 400. The cover window 500 may include at least one of glass, sapphire, and plastic. For example, the cover window 500 may be ultra thin glass or colorless polyimide. In an embodiment, the cover window 500 may have a structure in which a flexible polymer layer is disposed on one surface of a glass substrate, or the cover window 500 may have a structure including only a polymer layer.

FIG. 11 is an enlarged view of some elements in enlarged region A in FIG. 4 in a case where a voltage is applied to the electrode line 410 and the electrode layer 440, according to an embodiment. FIG. 12 is an enlarged view of region B in FIG. 8 in a case where a voltage is applied to the electrode line 410 and the electrode layer 440, according to an embodiment.

Referring to FIGS. 11 and 12, when a voltage is applied between the electrode lines 410 and the electrode layer 440, the light-shielding particles 432 included in the second light-shielding lines 430 may move toward the electrode lines 410. In other words, the light-shielding particles 432 may move to a point where the electrode lines 410 and the second light-shielding lines 430 illustrated in FIG. 7 cross each other. Accordingly, the light-shielding particles 432 may be concentrated and arranged in an area overlapping the electrode lines 410. Accordingly, in the example, the second light-shielding lines 430 including the light-shielding particles 432 may be arranged not in a line shape but in an island shape in an area overlapping the electrode lines 410.

In an embodiment, because the first light-shielding lines 420 are arranged to overlap the electrode lines 410 and extend in the first direction (e.g., the x direction), when a voltage is applied between the electrode lines 410 and the electrode layer 440, the light-shielding particles 432 of the second light-shielding lines 430 may be arranged in an area overlapping the first light-shielding lines 420. Thus, when the viewing angle limitation in the first direction (e.g., the x direction) is to be released, light blocking by the second light-shielding line 430 may be minimized or reduced.

The display device 1 according to an embodiment may be operated in a first mode in which the left-right viewing angle is limited (e.g., the left-right viewing angle is set to a viewing angle less than a maximum capable viewing angle of the display device 1) or in a second mode in which the left-right viewing angle is not limited (e.g., the left-right viewing angle is set to the maximum capable viewing angle of the display device 1). In the first mode, a voltage may not be applied to for the electrode line 410 and the electrode layer 440 that face each other with the second light-shielding lines 430 therebetween. In the second mode, a voltage may be applied to the electrode line 410 and the electrode layer 440 that face each other with the second light-shielding lines 430 therebetween.

In one or more embodiments, the second light-shielding lines 430 may be changed into a line shape or an island pattern shape, depending on whether a voltage is applied, such that traveling of light emitted from the sub-pixel in the first direction (e.g., the x direction) is controlled. For example, in the first mode, the second light-shielding lines 430 may be arranged in the form of a line, as illustrated in FIG. 7, and may prevent or minimize traveling of light emitted from the sub-pixel in the first direction (e.g., the x direction). In the second mode, the second light-shielding lines 430 may be arranged in the form of an island pattern such that the second light-shielding lines 430 overlap the first light-shielding lines 420, as illustrated in FIG. 11, and may improve light transmittance of the light emitted from the sub-pixel in the first direction (e.g., the x direction).

In a comparative example, when all of upper and lower electrode layers adjacent to the second light-shielding lines 430 are in the form of a single plate on the x-y plane, in the second mode in which a voltage is applied, none of the light-shielding particles 432 of the second light-shielding lines 430 overlap the first light-shielding lines 420, such that the second light-shielding lines 430 may have a relatively low transmittance.

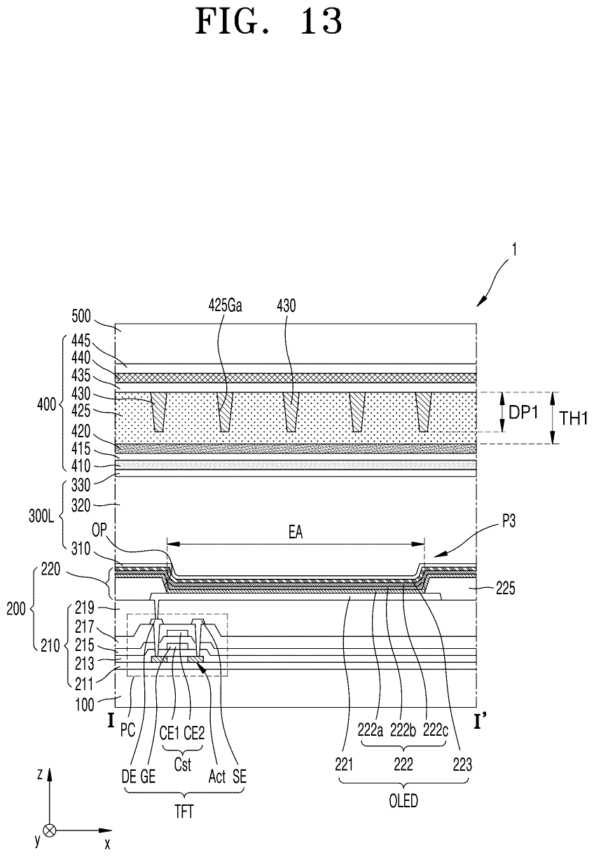

FIG. 13 is a cross-sectional view schematically illustrating the display device in FIG. 7, taken along line I-I in FIG. 7, according to another embodiment. FIG. 13 is a modification of an embodiment described with reference to FIGS. 8 to 10, and thus, differences are mainly described, and redundant descriptions are omitted.

Referring to FIG. 13, the organic layer 425 disposed on the first light-shielding lines 420 may include a plurality of grooves 425Ga that extend in the second direction (e.g., the y direction). In an embodiment, the groove 425Ga may be formed such that the groove 425Ga does not pass through the organic layer 425. For example, an upper surface of the organic layer 425 may be concave by the groove 425Ga. In other words, in a cross-sectional view, the organic layer 425 may have portions with upper surfaces having different heights from each other. For example, the organic layer 425 may include a convex portion having an upper surface at a relatively high level, and a concave portion having an upper surface at a relatively low level.

In an embodiment, a depth DP1 of the groove 425Ga may be less than a thickness TH1 of the organic layer 425. The depth DP1 of the groove 425Ga may be a distance in a direction perpendicular to an upper surface of the substrate 100 (e.g., the z direction) between the upper surface of the convex portion of the organic layer 425 and the upper surface of the concave portion of the organic layer 425.

In an embodiment, a side surface of the organic layer 425 exposed by the groove 425Ga may be inclined with respect to the upper surface of the organic layer 425.

In an embodiment, because the groove 425Ga does not pass through the organic layer 425, the second light-shielding lines 430 arranged in the groove 425Ga may be spaced apart from the first light-shielding lines 420 without being in contact. The organic layer 425 may be arranged between the second light-shielding lines 430 and the first light-shielding lines 420.

In an embodiment, the electrode layer 440 may be disposed directly on the organic layer 425. In other words, the organic layer 425 and the electrode layer 440 may be in contact with each other. The electrode layer 440 may be disposed directly on the second light-shielding lines 430.

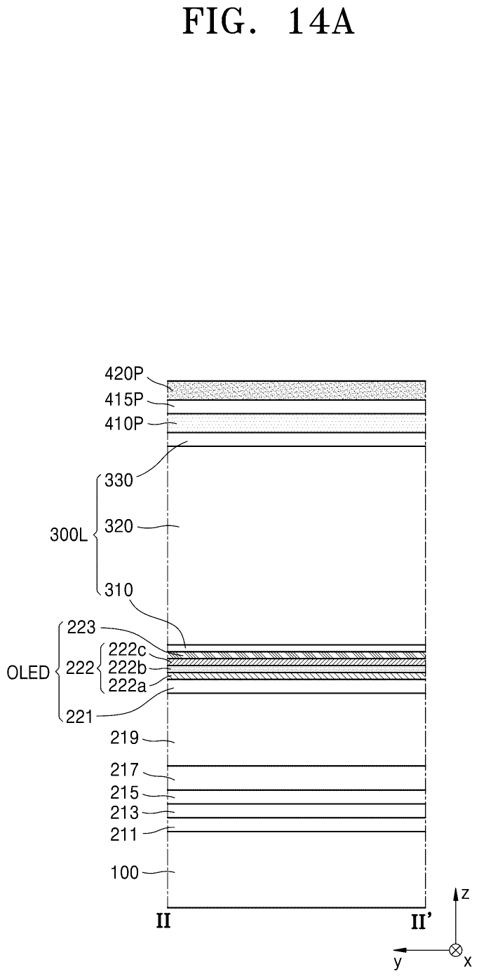

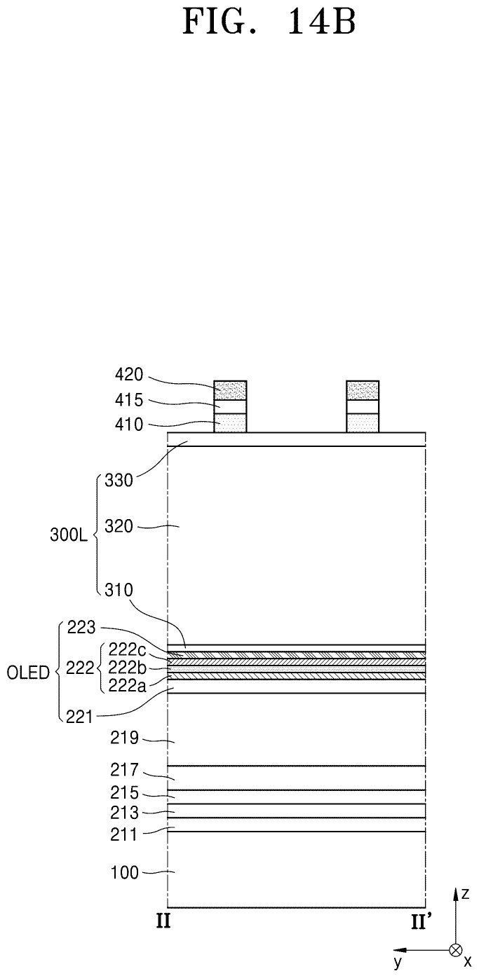

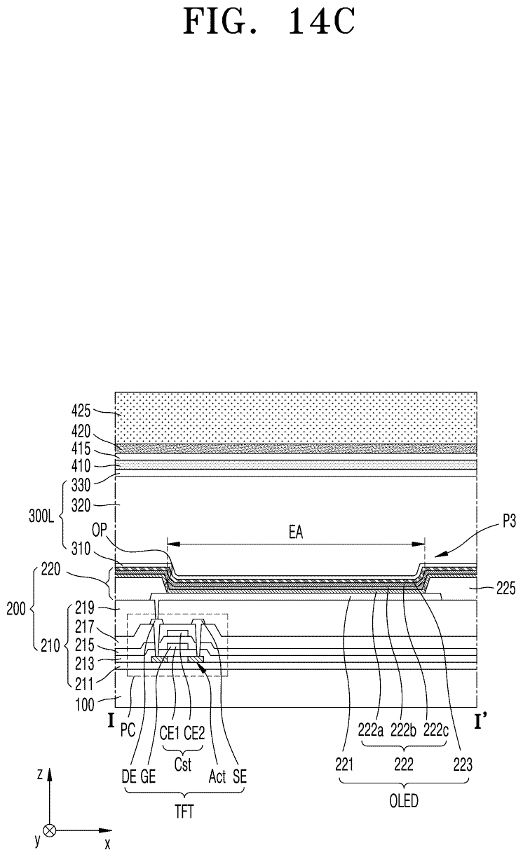

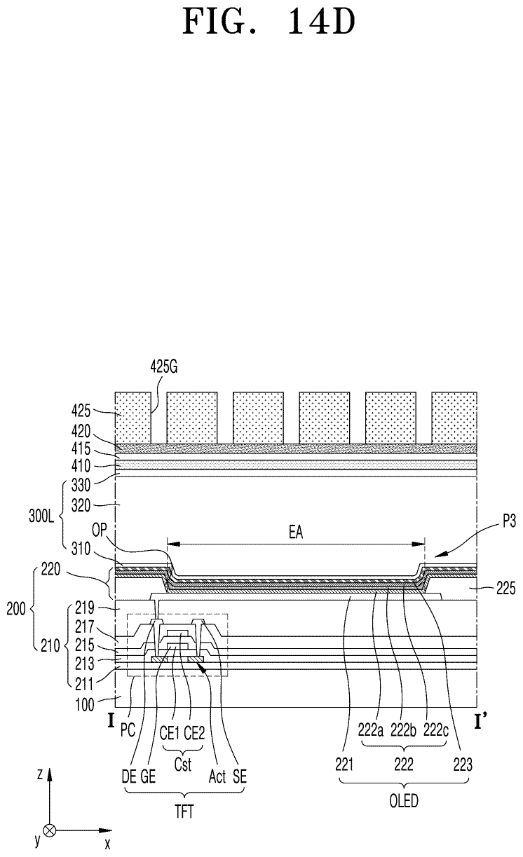

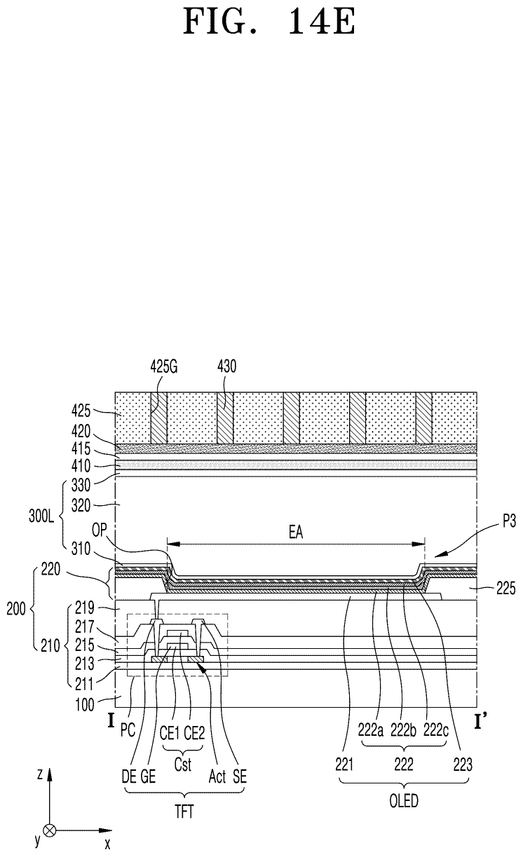

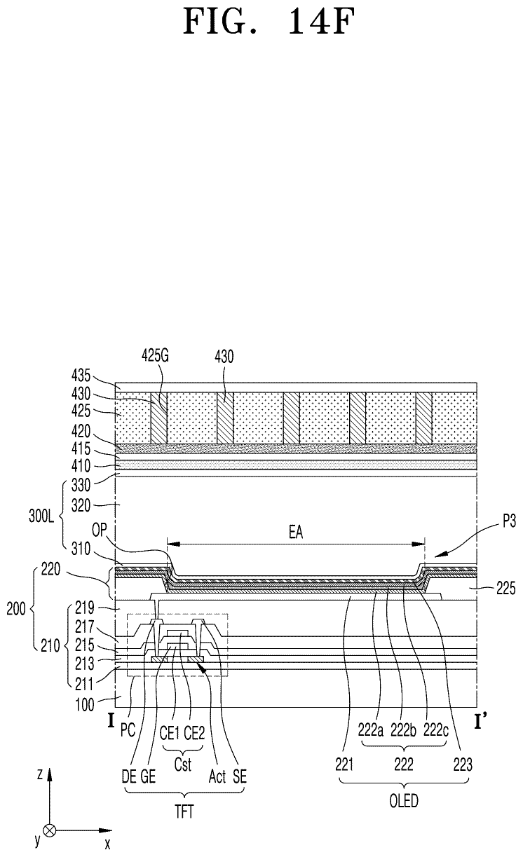

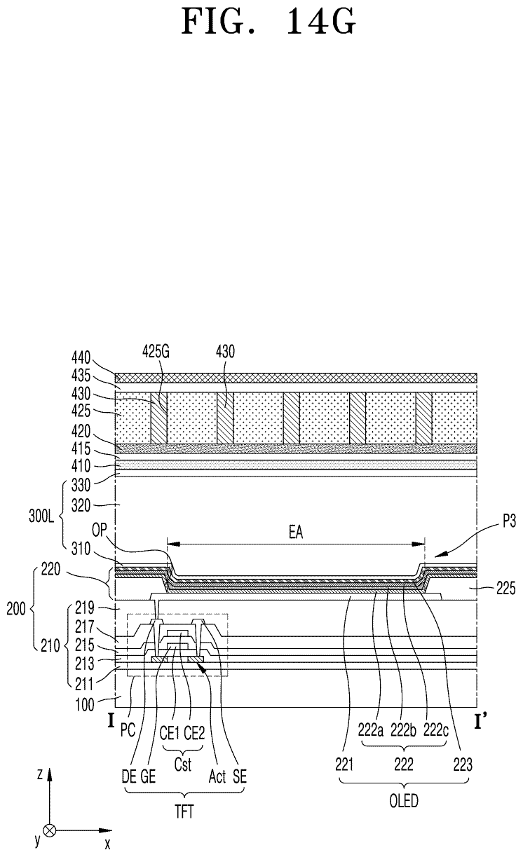

FIGS. 14A to 14G are cross-sectional views schematically illustrating a method of manufacturing the display device 1, according to an embodiment. FIGS. 14A to 14G illustrate a method of manufacturing the display device 1, according to an embodiment described with reference to FIGS. 6 to 12. FIGS. 14A and 14B illustrate a manufacturing method with reference to a cross-section of the display device 1 in FIG. 7, taken along line I-I′ in FIG. 7, and FIGS. 14C to 14G illustrate a manufacturing method with reference to a cross-section of the display device 1, taken along line II-II in FIG. 7.

Referring to FIGS. 14A and 14B, the method may include forming the display layer 200 including the pixel circuit layer 210 and the emission element layer 220 on the substrate 100, and the method may include forming the encapsulation layer 300L on the display layer 200.

Next, as illustrated in FIG. 14A, the method may include forming a preliminary electrode line 410P, a preliminary passivation layer 415P, and a preliminary first light-shielding line 420P on the encapsulation layer 300L such that the preliminary electrode line 410P, the preliminary passivation layer 415P, and the preliminary first light-shielding line 420P are sequentially stacked.

The preliminary electrode line 410P may include a conductive material. In an embodiment, the preliminary electrode line 410P may include a transparent conductive material. For example, the preliminary electrode line 410P may include a transparent conductive oxide such as, for example, ITO and IZO.

The preliminary passivation layer 415P may include, for example, an inorganic material.

The preliminary first light-shielding line 420P may include a light-shielding material. For example, the preliminary first light-shielding line 420P may include a black matrix. For example, the preliminary first light-shielding line 420P may include black dye such as, for example, carbon black.

Next, as illustrated in FIG. 14B, the method may include forming a plurality of electrode lines 410, the first passivation layer 415, and a plurality of first light-shielding lines 420. The method may include simultaneously etching the preliminary electrode line 410P, the preliminary passivation layer 415P, and the preliminary first light-shielding line 420P in association with forming the plurality of electrode lines 410, the first passivation layer 415, and the plurality of first light-shielding lines 420. Accordingly, the electrode lines 410, the first passivation layer 415, and the first light-shielding lines 420 may extend in the first direction (e.g., the x direction) and may be arranged to overlap each other.

In FIGS. 14A and 14B, by a manufacturing method according to an embodiment, the method may include sequentially stacking the preliminary electrode line 410P, the preliminary passivation layer 415P, and the preliminary first light-shielding line 420P on the encapsulation layer 300L and simultaneously etching the preliminary electrode line 410P, the preliminary passivation layer 415P, and the preliminary first light-shielding line 420P, so as to form the electrode lines 410, the first passivation layer 415, and the first light-shielding lines 420. However, one or more embodiments are not limited thereto.

In another embodiment, the method may include forming the electrode lines 410 on the encapsulation layer 300L through a sputtering process, without forming the preliminary electrode line 410P. Next, the method may include forming the preliminary passivation layer 415P and the preliminary first light-shielding line 420P on the electrode lines 410. The method may include removing a portion of the preliminary passivation layer 415P and the preliminary first light-shielding line 420P in association with forming the first passivation layer 415 and the first light-shielding lines 420 that overlap the electrode lines 410 and extend in the first direction (e.g., the x direction). A process of removing a portion of the preliminary passivation layer 415P and the preliminary first light-shielding line 420P may be, for example, an etching process.

Referring to FIG. 14C, the method may include forming the organic layer 425 on the first light-shielding lines 420. In an embodiment, the organic layer 425 may be fully cured.

Referring to FIG. 14D, the method may include forming, on the organic layer 425, the groove 425G extending in the second direction (e.g., the y direction) that crosses the first direction (e.g., the x direction). In other words, the groove 425G may be formed such that the groove 425G extends in a direction crossing the electrode lines 410 and the first light-shielding lines 420. The groove 425G may be formed such that the groove 425G passes through the organic layer 425.

In an embodiment, the method may include forming the groove 425G of the organic layer 425 by etching the organic layer 425. The etching process may be, for example, a dry etching process. Because the groove 425G of the organic layer 425 is formed by a dry etching process, a side surface of the organic layer 425 exposed by the groove 425G may be substantially perpendicular to the upper surfaces of the first light-shielding lines 420.

Referring to FIG. 14E, the method may include forming the second light-shielding lines 430 by injecting an electrophoretic solution into the groove 425G.

Because the groove 425G of the organic layer 425 extends in a direction crossing the electrode lines 410 and the first light-shielding lines 420, the second light-shielding lines 430 formed in the groove 425G may be formed such that the second light-shielding lines 430 extend in the second direction (e.g., the y direction) that crosses the electrode lines 410 and the first light-shielding lines 420.

In an embodiment, because the groove 425G of the organic layer 425 passes through the organic layer 425, the second light-shielding lines 430 formed in the groove 425G may be in contact with the electrode lines 410.

The electrophoretic solution injected into the groove 425G of the organic layer 425 may include the transparent fluid 431 and the light-shielding particles 432 dispersed in the transparent fluid 431, as illustrated in FIG. 9.

Referring to FIG. 14F, the method may include forming the capping layer 435 on the organic layer 425 and the second light-shielding lines 430. The capping layer 435 may include an organic material or an inorganic material. For example, forming the capping layer 435 may include coating and curing an organic material.

Referring to FIG. 14G, the method may include forming the electrode layer 440 on the capping layer 435. The electrode layer 440 may be formed such that the electrode layer 440 faces the electrode lines 410, with the second light-shielding lines 430 between the electrode layer 440 and the electrode lines 410. In an embodiment, the method may include forming the electrode layer 440 in the shape of a single plate disposed on the x-y plane. The electrode layer 440 may include a conductive material. In an embodiment, the electrode layer 440 may include a transparent conductive material. For example, the electrode layer 440 may include a transparent conductive oxide such as, for example, ITO and IZO.

Next, referring to FIG. 8, the method may include forming the cover window 500 on the electrode layer 440. In an embodiment, the method may include forming the second passivation layer 445 on the electrode layer 440, before forming the cover window 500. The second passivation layer 445 may be formed between the electrode layer 440 and the cover window 500.

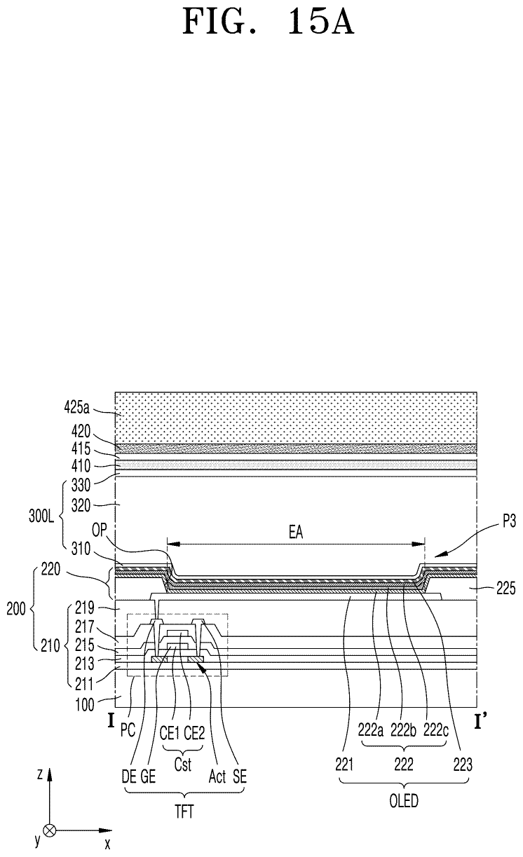

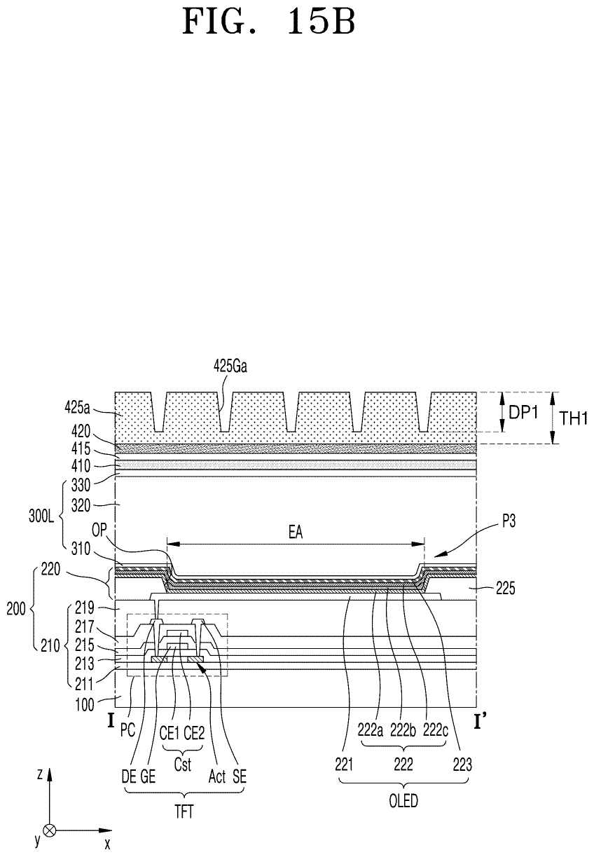

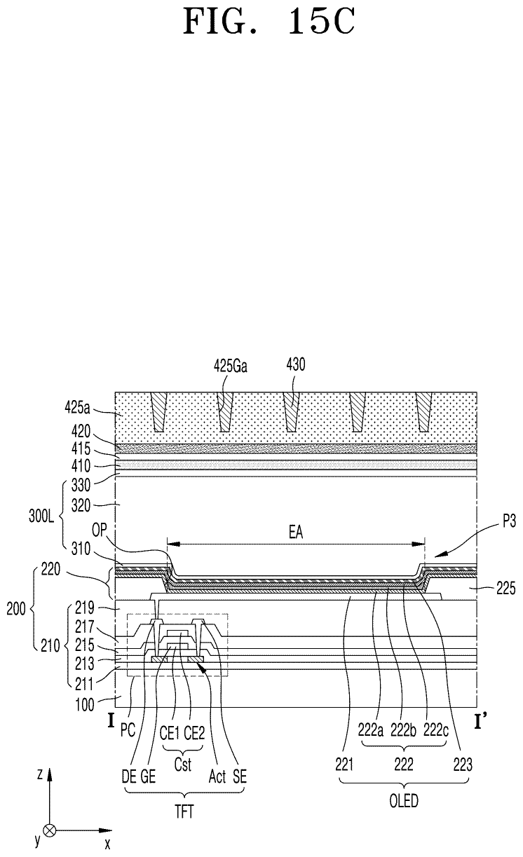

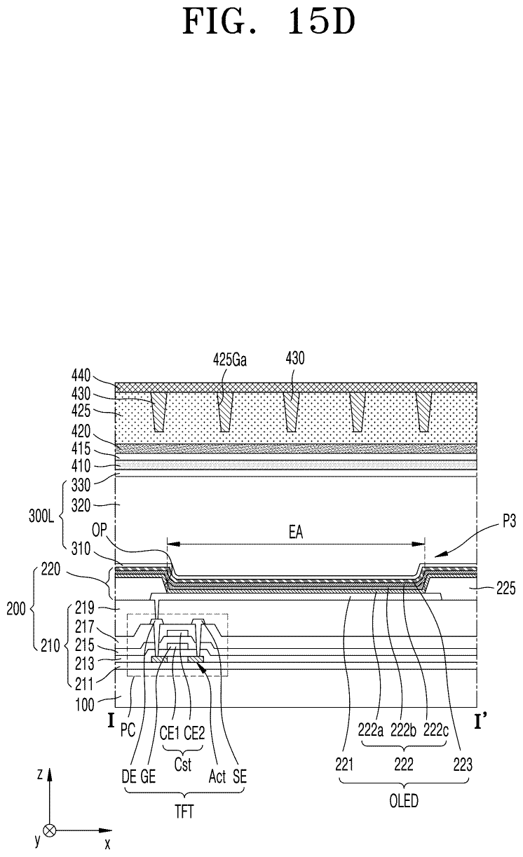

FIGS. 15A to 15D are cross-sectional views schematically illustrating a method of manufacturing a display device, according to another embodiment. FIGS. 15A to 15D illustrate a method of manufacturing the display device 1, according to another embodiment, described with reference to FIG. 13. FIGS. 15A to 15D illustrate a manufacturing method with reference to a cross-section of the display device 1 in FIG. 7, taken along line II-II′ in FIG. 7. In FIGS. 15A to 15D, a method of manufacturing elements under an organic layer 425a may be identical to the method described with reference to FIGS. 14A and 14B, descriptions of repeated elements are omitted for brevity.

Referring to FIG. 15A, the method may include forming the organic layer 425a on the first light-shielding lines 420. In an embodiment, the organic layer 425a may be in a pre-cured state.

Referring to FIG. 15B, the method may include forming the groove 425Ga on the organic layer 425. The groove 425Ga may extend in the second direction (e.g., the y direction) that crosses the first direction (e.g., the x direction). In other words, the groove 425Ga may be formed such that the groove 425G extends in a direction crossing the electrode lines 410 and the first light-shielding lines 420.

In an embodiment, the method may include forming the groove 425Ga of the organic layer 425 through an imprinting process. For example, the organic layer 425 may be in a pre-cured state, and the method may include pressing the organic layer 425 with an imprinting mold in association with forming the groove 425Ga in the organic layer 425. Accordingly, in a cross-sectional view, the organic layer 425 may include portions with upper surfaces having different heights from each other. For example, the organic layer 425 may include a convex portion having an upper surface at a relatively high level, and the organic layer 425 may include a concave portion having an upper surface at a relatively low level. In an embodiment, the method may include forming the groove 425Ga such that the depth DP1 of the groove 425Ga is less than the thickness TH1 of the organic layer 425.

In an embodiment, because the groove 425Ga is formed through an imprinting process, the side surface of the organic layer 425 exposed by the groove 425Ga may be inclined with respect to the upper surface of the organic layer 425.

Referring to FIG. 15C, the method may include forming the second light-shielding lines 430 by injecting an electrophoretic solution into the groove 425Ga.

Because the groove 425Ga of the organic layer 425 extends in a direction crossing the electrode lines 410 and the first light-shielding lines 420, the second light-shielding lines 430 formed in the groove 425Ga may be formed such that the groove 425Ga extends in the second direction (e.g., the y direction) that crosses the electrode lines 410 and the first light-shielding lines 420.

In an embodiment, as illustrated in FIG. 15C, because the depth DP1 of the groove 425Ga formed in the organic layer 425 less than the thickness TH1 of the organic layer 425, the second light-shielding lines 430 formed in the groove 425Ga may be spaced apart from the electrode lines 410 without being in contact.

The electrophoretic solution injected into the groove 425Ga of the organic layer 425 may include the transparent fluid 431 and the light-shielding particles 432 dispersed in the transparent fluid 431, as illustrated in FIG. 9.

Referring to FIG. 15D, the method may include forming the electrode layer 440 directly on the organic layer 425 and the second light-shielding lines 430. In other words, the organic layer 425 and the second light-shielding lines 430 may be in contact with the electrode layer 440. In an embodiment, because the organic layer 425 is in a pre-cured state, the electrode layer 440 may be formed directly on the organic layer 425. The electrode layer 440 may be formed such that the electrode layer 440 faces the electrode lines 410, with the second light-shielding lines 430 between the electrode layer 440 and the electrode lines 410. In an embodiment, the electrode layer 440 may be formed in the shape of a single plate disposed on the x-y plane. The electrode layer 440 may include a conductive material. In an embodiment, the electrode layer 440 may include a transparent conductive material. For example, the electrode layer 440 may include a transparent conductive oxide such as, for example, ITO and IZO.

Next, referring to FIG. 13, after the organic layer 425 is fully cured, the method may include forming the cover window 500 on the electrode layer 440. In an embodiment, before the cover window 500 is formed, the method may include forming the second passivation layer 445 on the electrode layer 440. The method may include forming the second passivation layer 445 between the electrode layer 440 and the cover window 500.

In the descriptions of the method and processes herein, the operations may be performed in a different order than the order illustrated and/or described, or the operations may be performed in different orders or at different times. Certain operations may also be left out of the method and processes, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

A display device according to an embodiment may include a first light-shielding line extending in a first direction and a second light-shielding line extending in a second direction that crosses the first direction. Accordingly, in the display device, a top-bottom viewing angle is limited in association with preventing an image from being reflected from a vehicle window while controlling a left-right angle. However, this effect is an example, and the scope of the one or more embodiments is not limited thereby.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate comprising a display area and a peripheral area that is disposed outside the display area;
a display layer in the display area, the display layer comprising an emission element;
an encapsulation layer that covers the display layer;
an electrode line on the encapsulation layer, the electrode line extending in a first direction;
a first light-shielding line on the electrode line, wherein the first light-shielding line extends in the first direction, overlaps the electrode line, and comprises a light-shielding material;
a second light-shielding line on the first light-shielding line, wherein the second light-shielding line extends in a second direction that crosses the first direction and comprises an electrophoretic solution; and
an electrode layer on the second light-shielding line.

2. The display device of claim 1, wherein the electrophoretic solution comprises a transparent fluid and light-shielding particles dispersed in the transparent fluid.

3. The display device of claim 1, wherein a width of the second light-shielding line is greater than a width of the first light-shielding line.

4. The display device of claim 1, further comprising an organic layer on the first light-shielding line, the organic layer comprising a groove that extends in the second direction,
wherein the second light-shielding line is arranged in the groove of the organic layer.

5. The display device of claim 4, wherein the groove passes through the organic layer.

6. The display device of claim 4, wherein a depth of the groove is less than a thickness of the organic layer.

7. The display device of claim 1, wherein the second light-shielding line contacts the first light-shielding line.

8. The display device of claim 1, wherein the second light-shielding line is spaced apart from the first light-shielding line.

9. The display device of claim 1, further comprising a capping layer between the second light-shielding line and the electrode layer.

10. The display device of claim 1, further comprising a passivation layer between the first light-shielding line and the electrode line.

11. A method of manufacturing a display device, the method comprising:
forming an electrode line on an encapsulation layer that covers an emission element, the electrode line extending in a first direction;
forming a first light-shielding line on the electrode line, wherein the first light-shielding line extends in the first direction, overlaps the electrode line, and comprises a light-shielding material;
forming an organic layer on the first light-shielding line;
forming a groove in the organic layer, the groove extending in a second direction that crosses the first direction;
forming a second light-shielding line by injecting an electrophoretic solution into the groove of the organic layer; and
forming an electrode layer on the second light-shielding line.

12. The method of claim 11, wherein the electrophoretic solution comprises a transparent fluid and light-shielding particles dispersed in the transparent fluid.

13. The method of claim 11, wherein a width of the second light-shielding line is greater than a width of the first light-shielding line.

14. The method of claim 11, wherein the forming of the groove comprises forming the groove by etching the organic layer.

15. The method of claim 11, wherein the forming of the groove comprises forming the groove through an imprinting process.

16. The method of claim 11, further comprising forming a preliminary electrode line and a preliminary first light-shielding line that are sequentially stacked,
wherein forming the electrode line and the first light-shielding line comprises etching the preliminary electrode line and the preliminary first light-shielding line, respectively.

17. The method of claim 11, further comprising forming a passivation layer between the electrode line and the first light-shielding line.

18. The method of claim 17, further comprising forming a preliminary electrode line, a preliminary passivation layer, and a preliminary first light-shielding line that are sequentially stacked,
wherein forming the electrode line, the passivation layer, and the first light-shielding line comprises etching the preliminary electrode line, the preliminary passivation layer, and the preliminary first light-shielding line, respectively.

19. The method of claim 11, further comprising forming a capping layer between the second light-shielding line and the electrode layer.

20. The method of claim 11, wherein the forming of the electrode line comprises forming the electrode line through a sputtering process, and
the forming of the first light-shielding line is after the forming of the electrode line.
